(19) United States
(12) Patent Application Publication
(10) Pub. No.: US 2023/0157141 A1
(43) Pub. Date: May 18, 2023

(54) BACKPLATE AND DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventor: Wu LI, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/966,043

(22) PCT Filed: Mar. 17, 2020
(86) PCT No.: PCT/CN2020/079712

§ 371 Date: Jul. 30, 2020

(30) Foreign Application Priority Data
Dec. 17, 2019 (CN) 201911304870.7

(51) Int. Cl. H10K 59/80; C09J 7/29; C09J 7/38

(52) U.S. Cl. CPC H10K 59/8794; C09J 7/29; C09J 7/38; C09J 2203/326; C09J 2301/41; C09J 2301/124; C09J 2301/302

(57) ABSTRACT

The present invention discloses a backplate and a display panel. The backplate includes a substrate layer. Material of the substrate layer includes a doped material. The doped material includes thermally conductive particles.

### FIELD OF INVENTION

The present invention is related to the field of display technology, and specifically, to a backplate and a display panel.

### BACKGROUND OF INVENTION

Flexible organic light-emitting diode (OLED) display panels are a popular development direction in the display industry because of their low power consumption, high resolution, fast response times, and bendability. The less thicknesses they have, the greater their market competitiveness is.

Currently, a polyimide (PI) material is often used as a substrate, and each functional film layer is sequentially disposed on it, and a polyethylene terephthalate (PET) backplate is then attached underneath to protect and support the substrate.

However, when a display panel is in operation, current heats up through a thin-film transistor (TFT) circuit. A layer of a heat sink is generally attached to a back of the backplate to facilitate heat dissipation, and its structure is generally composed of two or three kinds of a copper foil, a graphite sheet, and foam. This eventually leads to an increase in a thickness of the display panel, which is not conducive to thinning the display panel.

### SUMMARY OF INVENTION

The present invention provides a backplate and a display panel, to increase heat dissipation capacity of the backplate, thereby increasing heat dissipation capacity of the display panel. This reduces a thickness of the display panel without a need for heat sinks and realizes thinning the display panel.

The backplate and the display panel provided by the present invention increase the heat dissipation capacity of the backplate through doping a doped material into the backplate, thereby solving a technical problem of an increase in a thickness of the display panel due to disposing heat sinks on the display panel.

In order to solve the above technical problems, the present invention provides technical solutions as follows.

The present provides a backplate, including a substrate layer and a protective layer and an adhesive layer attached to two sides of the substrate layer. A side of the adhesive layer away from the substrate layer is provided with a peeling layer.

Material of the substrate layer includes a doped material, and the doped material includes thermally conductive particles.

In an embodiment of the present invention, the thermally conductive particles include at least one of carbon nanotubes, metal nanoparticles, or metal oxide nanoparticles.

In an embodiment of the present invention, the metal nanoparticles include silver nanoparticles or nickel nanoparticles.

In an embodiment of the present invention, the metal oxide nanoparticles include magnesium oxide nanoparticles or zinc oxide nanoparticles.

In an embodiment of the present invention, the doped material accounts for 0.01 to 5% of the substrate layer.

In an embodiment of the present invention, a thickness of the substrate layer ranges from 50 to 150 microns.

In an embodiment of the present invention, the adhesive layer includes a pressure sensitive adhesive, and a thickness of the pressure sensitive adhesive ranges from 13 to 50 microns.

In an embodiment of the present invention, a thickness of the backplate ranges from 50 to 300 microns.

According to the above purpose of the present invention, a display panel is provided. The display panel includes a backplate and an array substrate, an organic light-emitting diode (OLED) light-emitting layer, and a thin-film encapsulation layer disposed on the backplate in sequence. The backplate includes a substrate layer and a protective layer and an adhesive layer attached to two sides of the substrate layer.

Material of the substrate layer includes a doped material, and the doped material includes thermally conductive particles.

In an embodiment of the present invention, a side of the backplate facing the array substrate is provided with the adhesive layer.

In an embodiment of the present invention, the thermally conductive particles include at least one of carbon nanotubes, metal nanoparticles, or metal oxide nanoparticles.

In an embodiment of the present invention, the metal nanoparticles include silver nanoparticles or nickel nanoparticles.

In an embodiment of the present invention, the metal oxide nanoparticles include magnesium oxide nanoparticles or zinc oxide nanoparticles.

In an embodiment of the present invention, the doped material accounts for 0.01 to 5% of the substrate layer.

In an embodiment of the present invention, a thickness of the substrate layer ranges from 50 to 150 microns.

In an embodiment of the present invention, the adhesive layer includes a pressure sensitive adhesive, and a thickness of the pressure sensitive adhesive ranges from 13 to 50 microns.

In an embodiment of the present invention, a thickness of the backplate ranges from 50 to 300 microns.

Compared with the prior art, the present invention increases the heat dissipation capacity of the backplate through doping a doped material with excellent thermal conductivity into the backplate. Therefore, purposes of thinning a heat dissipation composite material, thinning a product, and reducing costs of the heat dissipation composite material is achieved.

### DESCRIPTION OF DRAWINGS

FIG. 1 is a structural diagram of a substrate layer provided by an embodiment of the present invention.

FIG. 2 is a structural diagram of a backplate provided by an embodiment of the present invention.

FIG. 3 is a structural diagram of a display panel provided by an embodiment of the present invention.

### DETAILED DESCRIPTION OF PREFERRED EMBODIMENTS

To further explain the technical means and effects of the present invention, the following refers to embodiments and drawings for detailed description. Obviously, the described embodiments are only for some embodiments of the present invention, instead of all embodiments. Based on the embodiments of the present invention, all other embodiments obtained by those skilled in the art without creative work fall into a protection scope of the present invention.

In the description of the present invention, it should be understood that terms such as “center,” “longitudinal,” “lateral,” “length,” “width,” “thickness,” “upper,” “lower,” “front,” “rear,” “left,” “right,” “vertical,” “horizontal,” “top,” “bottom,” “inside,” “outside,” “clockwise,” “counter-clockwise” as well as derivative thereof should be construed to refer to the orientation as then described or as shown in the drawings under discussion. These relative terms are for convenience of description, do not require that the present invention be constructed or operated in a particular orientation, and shall not be construed as causing limitations to the present invention. In addition, terms such as “first” and “second” are used herein for purposes of description and are not intended to indicate or imply relative importance or significance. Thus, features limited by “first” and “second” are intended to indicate or imply including one or more than one these features. In the description of the present invention, “a plurality of” relates to two or more than two, unless otherwise specified.

In the description of the present invention, it should be noted that unless there are express rules and limitations, the terms such as “mount,” “connect,” and “bond” should be comprehended in broad sense. For example, it can mean a permanent connection, a detachable connection, or an integrate connection; it can mean a mechanical connection, an electrical connection, or can communicate with each other; it can mean a direct connection, an indirect connection by an intermediate, or an inner communication or an interreaction between two elements. A person skilled in the art should understand the specific meanings in the present invention according to specific situations.

In the description of the present invention, unless specified or limited otherwise, it should be noted that, a structure in which a first feature is “on” or “beneath” a second feature may include an embodiment in which the first feature directly contacts the second feature, and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature, and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature, and may also include an embodiment in which the first feature is not right “beneath,” “below,” or “on bottom of” the second feature, or just means that the first feature has a sea level elevation less than the sea level elevation of the second feature.

The invention herein provides many different embodiments or examples for realizing different structures of the present invention. In order to simplify the invention of the present invention, components and settings of specific examples are described below. Of course, they are only examples and are not intended to limit the present invention. Furthermore, reference numbers and/or letters may be repeated in different examples of the present invention. Such repetitions are for simplification and clearness, which per se do not indicate the relations of the discussed embodiments and/or settings. Moreover, the present invention provides examples of various specific processes and materials, but the applicability of other processes and/or application of other materials may be appreciated by a person skilled in the art.

The present invention is directed to display panels in the prior art. Because their backplates do not have heat dissipation, the display panels need to be provided with other heat dissipation devices, which leads to a technical problem of an increase in a thickness of the display panels. Embodiments of the present invention can solve this defect.

An embodiment of the present invention provides a backplate, including a substrate layer and a protective layer and an adhesive layer attached to two sides of the substrate layer. A side of the adhesive layer away from the substrate layer is provided with a peeling layer.

Material of the substrate layer includes a doped material, and the doped material includes thermally conductive particles.

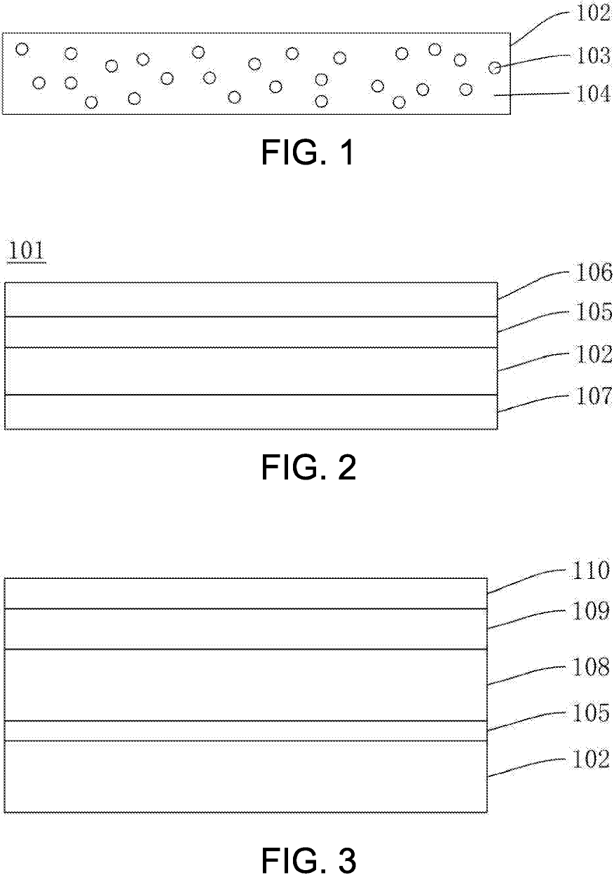

As shown in FIGS. 1 and 2, the backplate 101 provided by this embodiment of the present invention includes the substrate layer 102, the protective layer 107, the adhesive layer 105, and the peeling layer 106. The protective layer 107 and the adhesive layer 105 are sequentially attached to the two sides of the substrate layer. The peeling layer 106 is disposed on the side of the adhesive layer 105 away from the substrate layer 102. The material of the substrate layer 102 includes the doped material 103, and the doped material 103 includes thermally conductive particles.

In an actual implementation, when a display panel is in operation, current heats up through a thin-film transistor (TFT) circuit. A layer of a heat sink is generally attached to a back of the backplate to facilitate heat dissipation, and its structure is generally composed of two or three kinds of a copper foil, a graphite sheet, and foam. This eventually leads to the increase in the thickness of the display panel, which is not conducive to thinning the display panel. However, this embodiment increases heat dissipation capacity of the backplate through doping the doped material with excellent thermal conductivity into the backplate, thereby increasing heat dissipation capacity of the display panel. In this way, a heat dissipation composite material is thinned, a product is thinned, and costs of the heat dissipation composite material are reduced. In another aspect, the doped material can fill gaps between macromolecules in material of the backplate, thereby reducing heat insulation capacity of the backplate.

Furthermore, the thermally conductive particles include at least one of carbon nanotubes, metal nanoparticles, or metal oxide nanoparticles. In other words, the doped material 103 can be any one, a combination of any two, or a combination of any three of the carbon nanotubes, metal nanoparticles, and metal oxide nanoparticles.

Specifically, the carbon nanotubes have a good heat transfer performance, and the carbon nanotubes have a very large length-to-diameter ratio, so their heat exchange performance along a length direction is high, and their heat exchange performance in a vertical direction is relatively low. The carbon nanotubes can synthesize highly anisotropic thermally conductive materials with proper orientation. In addition, the carbon nanotubes have higher thermal conductivity, and as long as a composite material is doped with a small amount of the carbon nanotubes, the thermal conductivity of the composite material is greatly improved. This embodiment of the present invention can increase the heat dissipation capacity of the backplate 101 through doping the carbon nanotubes into the substrate layer 102.

A manufacturing method of the carbon nanotubes mainly includes: an arc discharge method, a laser ablation method, a chemical vapor deposition method (hydrocarbon gas pyrolysis method), a solid-phase pyrolysis method, a glow discharge method, a gas combustion method, and a polymerization synthesis method.

The metal nanoparticles include silver nanoparticles or nickel nanoparticles. These two kinds of nanoparticles are taken as an example herein, and other metal nanoparticles are not limited.

The silver nanoparticles and the nickel nanoparticles both have excellent thermal conductivity. The silver nanoparticles are metallic silver elements with a diameter of less than 100 nanometers, which generally ranges from 20 to 50 nanometers. The silver nanoparticles are silver particles composed of atomic structures, rather than silver ions. The silver nanoparticles are not charged, and they are solid powders, which are processed by physical-chemical methods from the metallic silver elements to metallic silver particles with a particle diameter of less than 100 nanometers. The nickel nanoparticles are not easy to manufacture compared to the silver nanoparticles, and are not described herein.

The metal oxide nanoparticles include magnesium oxide nanoparticles or zinc oxide nanoparticles. These two kinds of nanoparticles are taken as an example herein, and other metal oxide nanoparticles are not limited.

There are three main methods for manufacturing the magnesium oxide nanoparticles, which are a solid-phase synthesis method, a gas-phase synthesis method, and a liquid-phase synthesis method. The zinc oxide nanoparticles are manufactured by a wet chemical method. Various zinc-containing materials can be used as raw materials. Zinc is leached by acid leaching. After multiple purifications to remove impurities in the raw materials, basic zinc carbonate is obtained by precipitating, and nano-zinc oxide is finally obtained by calcining.

In this embodiment, the doped material accounts for 0.01 to 5% of the substrate layer.

In addition, the material of the substrate layer 102 further includes a PET material 104.

The PET material 104 is polyethylene terephthalate. The PET material 104 is a milky white or light yellow highly crystalline polymer, its surface is smooth and shiny. It is creep resistant, fatigue resistant, abrasion resistant, has good dimensional stability, low abrasion, and high hardness, and has the highest toughness among thermoplastics, making it have good electrical insulation performance and is less affected by temperature.

However, thermal conductivity of the PET material 104 is poor, resulting in poor thermal conductivity of the backplate 101. This embodiment increases the heat dissipation capacity of the backplate 101 through doping the doped material 103 into the substrate layer 102.

In this embodiment, the doped material 103 can be doped into the PET material 104 by a melt blending method, and a mixed material is formed as a film-shaped PET, and then the film-shaped PET is die-cut to obtain the substrate layer 102.

In this embodiment, as shown in FIG. 2, a thickness of the backplate 101 ranges from 50 to 300 microns, and a thickness of the substrate layer 102 ranges from 50 to 150 microns.

In another embodiment of the present invention, the thickness of the substrate layer 102 can range from 75 to 150 microns.

In this embodiment, the adhesive layer 105 can be a pressure sensitive adhesive. The adhesive layer 105 is attached to a side of the substrate layer 102. A thickness of the pressure sensitive adhesive ranges from 13 to 50 microns.

In another embodiment of the present invention, the thickness of the pressure sensitive adhesive can range from 13 to 25 microns.

In this embodiment, the substrate layer 102 and the adhesive layer 105 adopt a thin thickness, so the thickness of the backplate 101 is thin accordingly, which is beneficial to thinning the display panel.

In addition, the backplate 101 further includes the protective layer 107 and the peeling layer 106. The peeling layer 106 is attached on a side of the adhesive layer 105 away from the substrate layer 102. The protective layer 107 is attached on a side of the substrate layer 102 away from the adhesive layer 105.

The protective layer 107 can be a protective film, and the protective film can play a protective role and be used for anti-scratch protection of glass panels, acrylic panels, PC boards, screen displays, etc. PET protective films can be divided into high viscosity PET protective films, medium viscosity PET protective films, and low viscosity PET protective films according to differences of viscosities. Products using these three kinds of protective films with different viscosity are different accordingly. The PET protective films can also be divided into different protective films according to a number of layers and can be divided into single-layer PET protective films, double-layer PET protective films, and three-layer PET protective films according to the number of layers. These different kinds of protective films are not much different, but the number of layers is different. The protective layer 107 can be selected according to actual conditions, which is not limited herein.

The release layer 106 can be a release film, which is coated with a release agent on a PET material. The release film is used for die cutting in a process of laminating some protective films, which means that a PET release film only plays an auxiliary role.

The protective layer 107 and the peeling layer 106 are removed in different processes of the display panel.

As shown in FIG. 3, which is a display panel provided by this embodiment. The display panel includes the backplate 101 in the above embodiments. The protective layer 107 and the peeling layer 106 in the backplate 101 are all removed.

The display panel includes a substrate layer 102, a adhesive layer 105 disposed on the substrate layer 102, an array substrate 108 disposed on the adhesive layer 105, an organic light-emitting diode (OLED) light-emitting layer 109 disposed on the array substrate 108, and a thin-film encapsulation layer 110 disposed on the OLED light-emitting layer 109.

A side of the backplate 101 disposed with the adhesive layer 105 faces the array substrate 108 to facilitate attachment between the backplate 101 and the array substrate 108.

The display panel provided by the embodiments of the present invention can be used in various mobile terminals and displays, including flexible display screens, rigid display screens, and various industrial displays and commercial displays.

In summary, the backplate is doped with the doped material with excellent thermal conductivity, thereby increasing the heat dissipation capacity of the backplate. Also, the doped material can fill gaps between macromolecules in the backplate, thereby reducing heat insulation capacity of the backplate. In this way, a heat dissipation composite material is thinned, a product is thinned, and costs of the heat dissipation composite material are reduced. The backplate has an ability of heat dissipation, so the display panel does not need an additional heat dissipation device, thereby facilitating thinning of the display panel.

In the above embodiments, the descriptions of the various embodiments are different in emphases, for contents not described in detail, please refer to related description of other embodiments.

The backplate and the display panel provided by embodiments of the present invention are described in detail above, and the description of embodiments above is only for helping to understand technical solutions of the present invention and its core idea. Understandably, for a person of ordinary skill in the art can make various modifications of the technical solutions of the embodiments of the present invention above. However, it does not depart from the scope of the technical solutions of the embodiments of the present invention.

What is claimed is:

1. A backplate, comprising a substrate layer and a protective layer and an adhesive layer attached to two sides of the substrate layer;
wherein a side of the adhesive layer away from the substrate layer is provided with a peeling layer; and
wherein material of the substrate layer comprises a doped material, and the doped material comprises thermally conductive particles.

2. The backplate according to claim 1, wherein the thermally conductive particles comprise at least one of carbon nanotubes, metal nanoparticles, or metal oxide nanoparticles.

3. The backplate according to claim 2, wherein the metal nanoparticles comprise silver nanoparticles or nickel nanoparticles.

4. The backplate according to claim 2, wherein the metal oxide nanoparticles comprise magnesium oxide nanoparticles or zinc oxide nanoparticles.

5. The backplate according to claim 1, wherein the doped material accounts for 0.01 to 5% of the substrate layer.

6. The backplate according to claim 1, wherein a thickness of the substrate layer ranges from 50 to 150 microns.

7. The backplate according to claim 1, wherein the adhesive layer comprises a pressure sensitive adhesive, and a thickness of the pressure sensitive adhesive ranges from 13 to 50 microns.

8. The backplate according to claim 1, wherein a thickness of the backplate ranges from 50 to 300 microns.

9. A display panel, comprising a backplate and an array substrate, an organic light-emitting diode (OLED) light-emitting layer, and a thin-film encapsulation layer disposed on the backplate in sequence;
wherein the backplate comprises a substrate layer and a protective layer and an adhesive layer attached to two sides of the substrate layer; and
wherein material of the substrate layer comprises a doped material, and the doped material comprises thermally conductive particles.

10. The display panel according to claim 9, wherein a side of the backplate facing the array substrate is provided with the adhesive layer.

11. The display panel according to claim 9, wherein the thermally conductive particles comprise at least one of carbon nanotubes, metal nanoparticles, or metal oxide nanoparticles.

12. The display panel according to claim 11, wherein the metal nanoparticles comprise silver nanoparticles or nickel nanoparticles.

13. The display panel according to claim 11, wherein the metal oxide nanoparticles comprise magnesium oxide nanoparticles or zinc oxide nanoparticles.

14. The display panel according to claim 9, wherein the doped material accounts for 0.01 to 5% of the substrate layer.

15. The display panel according to claim 9, wherein a thickness of the substrate layer ranges from 50 to 150 microns.

16. The display panel according to claim 9, wherein the adhesive layer comprises a pressure sensitive adhesive, and a thickness of the pressure sensitive adhesive ranges from 13 to 50 microns.

17. The display panel according to claim 9, wherein a thickness of the backplate ranges from 50 to 300 microns.
